(19) United States
(12) Patent Application Publication
(10) Pub. No.: US 2016/0139627 A1
(43) Pub. Date: May 19, 2016

(54) SUPPORTING PLATE, TOUCH DISPLAY PANEL AND TOUCH DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Anhui (CN)

(72) Inventors: Zhixiang FANG, Beijing (CN); Ming HU, Beijing (CN); Taofeng XIE, Beijing (CN)

(21) Appl. No.: 14/744,451

(22) Filed: Jun. 19, 2015

(30) Foreign Application Priority Data
Nov. 19, 2014 (CN) 201410664468.0

(51) Int. Cl. G06F 1/16; H05K 7/18; G06F 3/041

(52) U.S. Cl. CPC G06F 1/16; G06F 3/0412; H05K 7/18

(57) ABSTRACT

Embodiments of the invention provide a supporting plate, a touch display panel and a touch display device. The supporting plate is used in a touch display panel, which includes a touch screen and a display panel. The supporting plate is arranged between the touch screen and the display panel in a region corresponding to a non-active area of the touch display panel, and includes a supporting part used for supporting the touch screen, wherein at least part of the top surface of the supporting part is fixedly connected to the touch screen, and the top surface of the supporting part is not higher than the top surface of the touch screen to be fixed, so as to expose the entire top surface of the touch screen. According to embodiments of the invention, assembling of the touch screen is easier and design of narrow or no bezel can be achieved.

### CROSS-REFERENCE TO RELATED APPLICATION

This application claims priority to Chinese Patent Application No. 201410664468.0, filed on Nov. 19, 2014, the disclosure of which is incorporated by reference herein in its entirety.

### FIELD OF THE INVENTION

The present invention relates to the field of display technology, and particularly relates to a supporting plate, a touch display panel including the supporting plate and a touch display device including the touch display panel.

### BACKGROUND OF THE INVENTION

With increase of touch display devices in size, attaching process for a touch screen thereof becomes more difficulty. For a large size display panel based touch display device, the conventional surface attaching adopted between the touch screen and the display panel results in relatively high requirements in processing, while the conventional frame attaching adopted between the touch screen and the display panel is hard to satisfy the demands on design of narrow bezel.

For example, FIG. 1 is a sectional diagram of a touch display device in the prior art. In FIG. 1, the conventional frame attaching is adopted between a touch screen 3 and a display panel 6, wherein the touch screen 3 is positioned between a cover plate 1 and a housing 2, and the touch screen 3 is attached, by a tape 4, to a plastic frame 5 which is positioned at the inner side of the housing 2. From FIG. 1 it can be seen that the width of the cover plate 1 has a direct impact on the narrow bezel effect of the touch display device, thereby weakening a user's visual experience.

### SUMMARY OF THE INVENTION

In view of the above technical problems existing in the prior art, embodiments of the present invention provide a supporting plate, a touch display panel including the supporting plate and a touch display device including the touch display panel, for reducing the difficulty of attaching a touch screen and achieving design of narrow bezel or no bezel.

According to an embodiment of the present invention, there is provided a supporting plate, the supporting plate being used in a touch display panel, the touch display panel including a touch screen and a display panel, wherein the supporting plate is arranged between the touch screen and the display panel and is arranged in a region corresponding to a non-active area of the touch display panel, and the supporting plate includes a supporting part for supporting the touch screen, wherein at least part of the top surface of the supporting part is fixedly connected to the touch screen, and the top surface of the supporting part is not higher than the top surface of the touch screen to be fixed, so as to expose the entire top surface of the touch screen.

The supporting plate may further include at least one fixing part arranged below the supporting part, and the fixing part is used for fixedly connecting the supporting plate to a housing arranged around the display panel.

The supporting part may include a horizontal part and a vertical part, which is connected to one end of the horizontal part and protrudes from the top surface of the horizontal part, and the top surface of the horizontal part is used as a connecting surface for fixedly connecting to the bottom surface of the touch screen.

The top surface of the supporting part may be used as the connecting surface for fixedly connecting to the bottom surface of the touch screen.

A tape may be arranged on the connecting surface, and the tape is used for attaching the touch screen with the supporting plate.

The tape may cover the entire connecting surface.

The connecting surface may be provided thereon with one or more recesses, and a tape is arranged within the one or more recesses and can be in contact with the bottom surface of the touch screen, so that the touch screen and the supporting plate are attached to each other.

According to an embodiment of the present invention, there is provided a touch display panel, including the above supporting plate provided by embodiments of the present invention, the touch display panel further including a touch screen and a display panel, wherein the supporting plate is arranged between the touch screen and the display panel, and a supporting part of the supporting plate is used for supporting the touch screen, wherein the supporting plate further includes at least one fixing part arranged below the supporting part, and a matching part, which is capable of being fixedly connected with the fixing part, is arranged on a housing arranged around the display panel, so as to fixedly connect the supporting plate to the housing.

The fixing part may be a protrusion protruding from the bottom surface of the supporting part, the matching part may be a hole corresponding to the protrusion.

According to an embodiment of the present invention, there is provided a touch display device, including the above touch display panel provided by the embodiment of the present invention.

According to embodiments of the present invention, by arranging the touch screen above the supporting plate, it not only reduces the difficulty of attaching the touch screen, so that the assembling of the touch screen is easier, but also can achieve design of narrow bezel or no bezel, thereby improving the visual effect.

### BRIEF DESCRIPTION OF THE DRAWINGS

FIG. 1 is a sectional view of a touch display device in the prior art.

FIG. 2 is a sectional view of a supporting plate provided by a first embodiment of the present invention.

FIG. 3 is a sectional view of a supporting plate provided by a second embodiment of the present invention.

FIG. 4 is a sectional view of a touch display device provided by the first embodiment of the present invention.

FIG. 5 is a sectional view of a touch display device provided by the second embodiment of the present invention.

FIG. 6 is a top view of the touch display device of FIG. 4.

FIG. 7 is a top view of the touch display device of FIG. 5.

### DETAILED DESCRIPTION OF THE INVENTION

To make the person skilled in the art better understand the technical solutions of the present invention, the present invention will be described in detail below with reference to the accompanying drawings and specific embodiments.

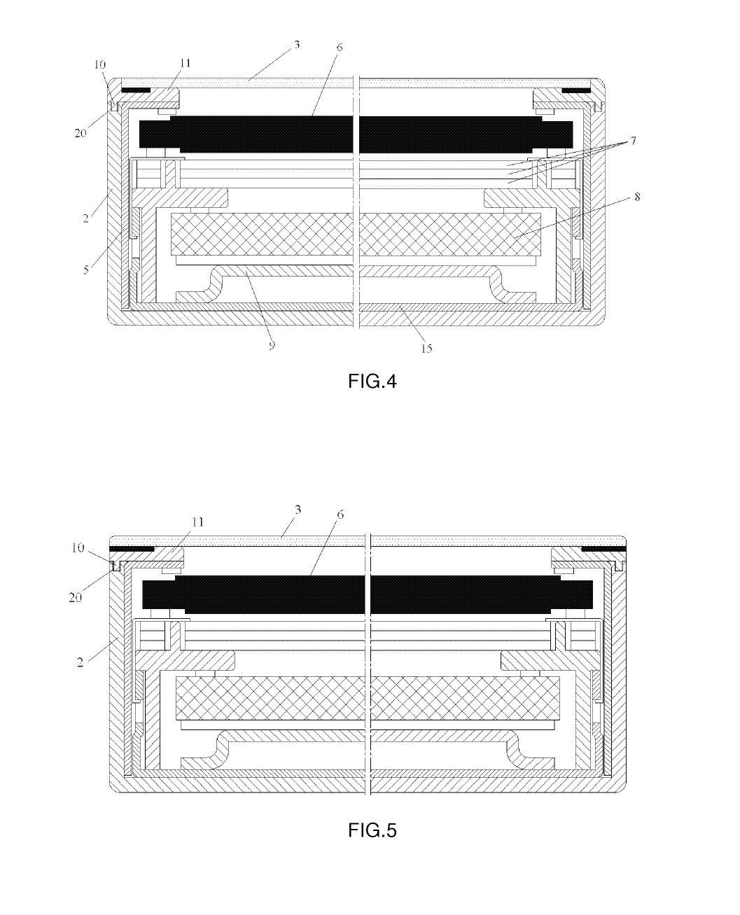

Unless stated otherwise, direction terms such as “top” and “bottom” mentioned in embodiments of the present invention refer to the top and bottom indicated in the drawings, such as the “top” and “bottom” indicated in FIGS. 2 and 3.

Embodiments of the present invention provide a supporting plate, as shown in FIGS. 2 and 3. The supporting plate 11 is used in a touch display panel, and is arranged in a region corresponding to a non-active area of the touch display panel. The touch display panel includes a touch screen 3 and a display panel (not shown in FIGS. 2 and 3) positioned under the touch screen 3. The supporting plate 11 is arranged between the touch screen 3 and the display panel, and includes a supporting part 12 for supporting the touch screen 3, wherein at least part of the top surface of the supporting part 12 is fixedly connected to the touch screen 3, and the top surface of the supporting part 12 is not higher than the top surface of the touch screen 3 to be fixed, so as to expose the entire top surface of the touch screen 3.

In embodiments of the present invention, compared to the conventional surface attaching or frame attaching adopted in the prior art, the touch screen 3 is arranged above the supporting plate 11, so that the assembling of the touch screen is easier and the difficulty of attaching the touch screen is reduced. In addition, because the entire top surface of the touch screen 3 is exposed fully, design of narrow bezel or no bezel can be achieved for the touch display panel, which facilitates the visual effect of the touch display panel to be improved.

Moreover, the supporting plate 11 further includes at least one fixing part 10 arranged below the supporting part 12, and the fixing part 10 is used for fixedly connecting the supporting plate 11 to a housing arranged around the display panel. For example, as shown in FIGS. 4 and 5, a housing 2 is arranged around a display panel 6, and a matching part 20 is arranged at a position, on the housing 2, corresponding to the fixing part 10 of the supporting plate 11, thereby causing the fixing part 10 to correspond to the matching part 20, and the fixing part 10 can match with the matching part 20 corresponding thereto, so that the supporting plate 11 is fixedly connected to the housing 2.

In addition, the fixing part 10 matching with the matching part 20 corresponding thereto can also realize a positioning function, so that the touch screen 3 and the display panel 6 can be aligned precisely.

When assembling the touch screen 3 with the display panel 6, the touch screen 3 may be fixedly connected to the supporting plate 11 first, and then the supporting plate 11 is fixedly connected to the housing 2 arranged around the display panel 6. Alternatively, the supporting plate 11 may be fixedly connected to the housing 2 arranged around the display panel 6 first, and then the touch screen 3 is fixedly connected to the supporting plate 11. As such, the assembling process of the touch screen 3 is simplified.

According to the first embodiment of the present invention, as shown in FIG. 2, the supporting part 12 of the supporting plate 11 includes a horizontal part and a vertical part, which is connected to one end of the horizontal part and protrudes from the top surface of the horizontal part. In the present embodiment, the top surface of the horizontal part is used as a connecting surface for fixedly connecting to the bottom surface of the touch screen 3.

According to the present embodiment, demands on design of narrow bezel can be satisfied by only adjusting the width of the vertical part (i.e., the width of the vertical part in a horizontal direction in FIG. 2), thereby realizing the visual effect of the narrow bezel. In addition, the vertical part can block ends of the touch screen 3, prevent the touch screen 3 from shifting, and have an assistance positioning function.

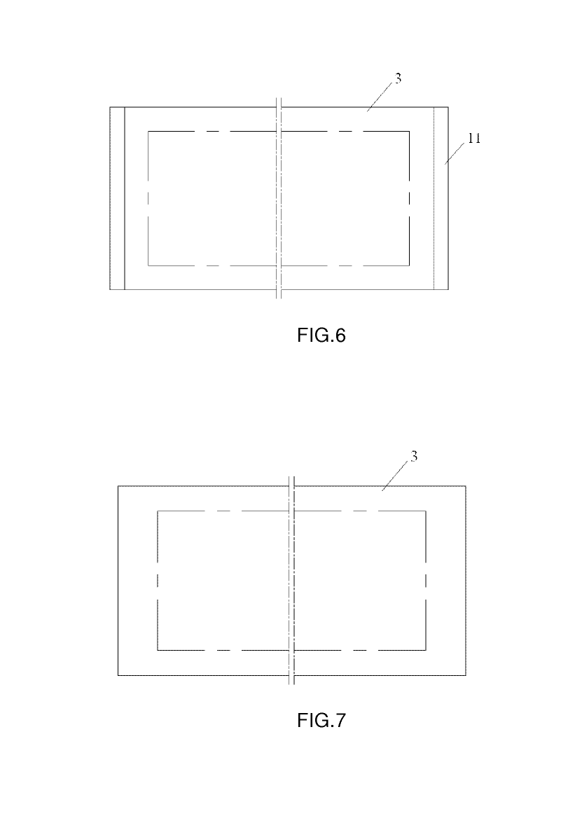

FIG. 4 is a sectional view of the touch display device that has been assembled in the present embodiment, and FIG. 6 is a top view of the touch display device of FIG. 4. From FIGS. 4 and 6 it can be seen that the top surface of the touch screen 3 is not being covered at all, so that viewers can have a better visual experience.

According to the second embodiment of the present invention, as shown in FIG. 3, the top surface of the supporting part 12 is used as the connecting surface for fixedly connecting to the bottom surface of the touch screen 3. In the present embodiment, the touch screen 3 covers the supporting plate 11 entirely, so that design of no bezel can be realized, and the visual effect can be further improved.

FIG. 5 is a sectional view of the touch display device that has been assembled in the present embodiment, and FIG. 7 is a top view of the touch display device of FIG. 5. From FIGS. 5 and 7 it can be seen that the touch screen 3 covers the supporting plate 11 entirely, so that viewers can experience the visual effect of no bezel.

Manner of fixed connection between the supporting plate 11 and the touch panel 3 is not limited in the present invention. For example, as shown in FIGS. 2 and 3, a tape 4 may be arranged on the connecting surface, and the tape 4 is used for attaching the touch screen 3 with the supporting plate 11, that is, the supporting plate 11 and the touch panel 3 are fixedly connected to each other through the tape 4.

The tape 4 may be a double side tape, one side of the double side tap is attaching with the connecting surface, and the other side of the double side tape is attaching with the bottom surface of the touch panel 3. The fixed connection with the tape 4 has advantages of simplicity in operation and high re-workability, that is, it is easy to be disassembled and repaired in a case where a shifting in attaching the touch screen 3 occurs.

Specifically, the tape 4 may cover part of the connecting surface or the entire connecting surface, and obviously, covering the entire connecting surface can increase the attaching area and enhance the attaching stability.

Alternatively, one or more recesses may be arranged on the connecting surface, the tape 4 may be arranged within the one or more recesses, and the top surface of the tape 4 is flush with the connecting surface, so that the tape 4 can be in contact with the bottom surface of the touch screen 3, so that the touch screen 3 and the supporting plate 11 are attached to each other. This attaching manner has the advantage of ensuring the flatness of the touch screen 3, thereby achieving a better visual effect.

Embodiments of the present invention further provide a touch display panel, including any one of the above supporting plate provided by embodiments of the present invention, and the touch display panel further includes a touch screen and a display panel, wherein the supporting part of the supporting plate is used for supporting the touch screen. The supporting plate further includes at least one fixing part arranged below the supporting part, and a matching part, which is capable of being fixedly connected with the fixing part, is arranged on a housing arranged around the display panel, so that the supporting plate is fixedly connected to the housing.

For example, as shown in FIGS. 4 and 5, the supporting plate 11 is used for supporting the touch screen 3, the supporting plate 11 further includes at least one fixing part 10, and the matching part 20, which is capable of being fixedly connected with the fixing part 10, is arranged on the housing 2 arranged around the display panel 6, so that the supporting plate 11 is fixedly connected to the housing 2.

Specifically, the fixing part 10 may be a protrusion (e.g., a cylindrical piece) protruding from the bottom surface of the supporting part 12 of the supporting plate 11, the matching part 20 may be a hole corresponding to the protrusion. Obviously, other manners of fixed connection may be adopted for the fixing part 10 and the matching part 20, and will not be described here.

Furthermore, embodiments of the present invention further provide a touch display device, including the above touch display panel provided by embodiments of the present invention.

For example, as shown in FIG. 4, the touch display device includes a touch display panel, which includes the supporting plate 11, the touch screen 3 and the display panel 6, wherein the supporting plate 11 is used for supporting the touch screen 3, at least one fixing part 10 is arranged below the supporting part 12 of the supporting plate 11, and a matching part 20, which is capable of being fixedly connected with the fixing part 10, is arranged on the housing 2 arranged around the display panel 6.

In FIG. 4, an optical film set 7 and a light source 8 are successively arranged below the display panel 6. In addition, a plastic frame 5 having a function of a buffer is arranged at the inner side of the housing 2, a back plate 15 having a function of supporting is arranged at the inner side of the bottom of the housing 2, and a plurality of reinforcing parts 9 are arranged around the back plate 15 and the plastic frame 5, so that the internal structure of the touch display device is more firm and stable.

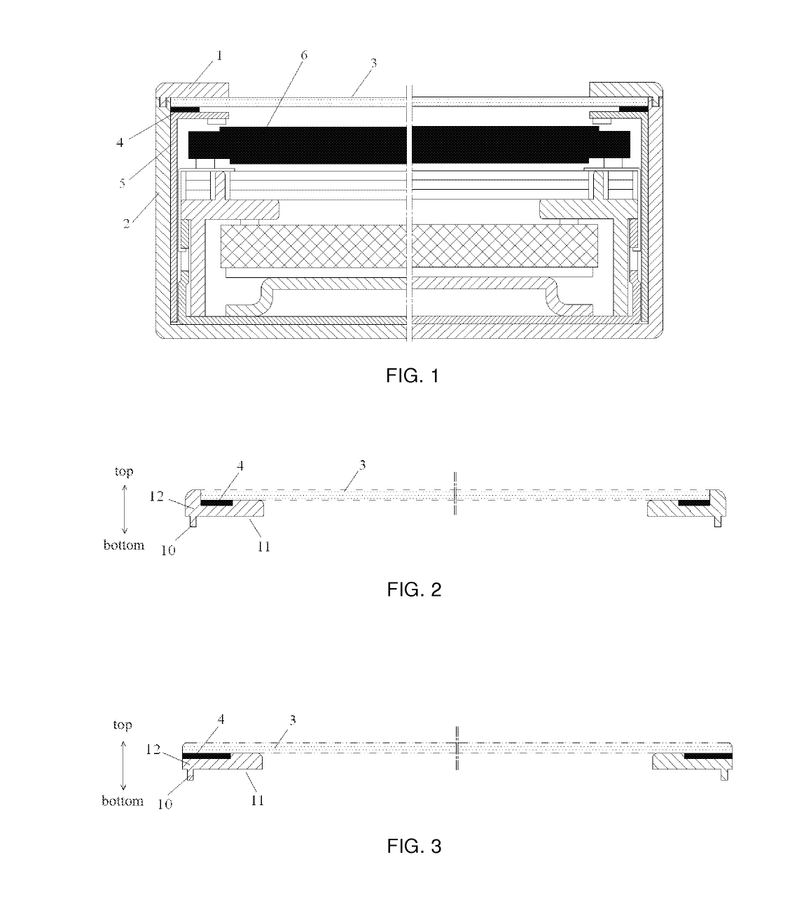

In FIGS. 1 and 5, elements similar to those in FIG. 4 will not be described here, and will not be indicated in FIGS. 1 and 5.

According to embodiments of the present invention, by arranging the touch screen above the supporting plate, it not only reduces the difficulty of attaching the touch screen, so that the assembling of the touch screen is easier, but also can achieve design of narrow bezel or no bezel, thereby improving the visual effect.

It should be understood that, the above embodiments are merely used for explaining the principle of the present invention, rather than limiting the present invention thereto, the person skilled in the art can make various variations and modifications without departing from the spirit and essence of the present invention. These variations and modifications are also construed as falling within the protection scope of the present invention.

1. A supporting plate, which is used in a touch display panel, the touch display panel including a touch screen and a display panel, wherein the supporting plate is arranged between the touch screen and the display panel, and is arranged in a region corresponding to a non-active area of the touch display panel, and the supporting plate includes a supporting part for supporting the touch screen, wherein at least part of the top surface of the supporting part is fixedly connected to the touch screen, and the top surface of the supporting part is not higher than the top surface of the touch screen to be fixed, so as to expose the entire top surface of the touch screen.

2. The supporting plate of claim 1, wherein the supporting plate further includes at least one fixing part arranged below the supporting part, and the fixing part is used for fixedly connecting the supporting plate to a housing arranged around the display panel.

3. The supporting plate of claim 1, wherein the supporting part includes a horizontal part and a vertical part, which is connected to one end of the horizontal part and protrudes from the top surface of the horizontal part, and the top surface of the horizontal part is used as a connecting surface for fixedly connecting to the bottom surface of the touch screen.

4. The supporting plate of claim 1, wherein the top surface of the supporting part is used as a connecting surface for fixedly connecting to the bottom surface of the touch screen.

5. The supporting plate of claim 3, wherein a tape is arranged on the connecting surface and the tape is used for attaching the touch screen with the supporting plate.

6. The supporting plate of claim 4, wherein a tape is arranged on the connecting surface and the tape is used for attaching the touch screen with the supporting plate.

7. The supporting plate of claim 5, wherein the tape covers the entire connecting surface.

8. The supporting plate of claim 6, wherein the tape covers the entire connecting surface.

9. The supporting plate of claim 3, wherein one or more recesses are arranged on the connecting surface, and a tape is arranged within the one or more recesses and is capable of being in contact with the bottom surface of the touch screen, so that the touch screen and the supporting plate are attached to each other.

10. The supporting plate of claim 4, wherein one or more recesses are arranged on the connecting surface, and a tape is arranged within the one or more recesses and is capable of being in contact with the bottom surface of the touch screen, so that the touch screen and the supporting plate are attached to each other.

11. A touch display panel, including a supporting plate, a touch screen and a display panel, the supporting plate being arranged between the touch screen and the display panel and being arranged in a region corresponding to a non-active area of the touch display panel, the supporting plate including a supporting part used for supporting the touch screen, wherein at least part of the top surface of the supporting part is fixedly connected to the touch screen, and the top surface of the supporting part is not higher than the top surface of the touch screen to be fixed, so as to expose the entire top surface of the touch screen, and
the supporting plate further includes at least one fixing part arranged below the supporting part, and a matching part, which is capable of being fixedly connected with the fixing part, is arranged on a housing arranged around the display panel, so that the supporting plate is fixedly connect to the housing.

12. The touch display panel of claim 11, wherein the fixing part is a protrusion protruding from the bottom surface of the supporting part, and the matching part is a hole corresponding to the protrusion.

13. A touch display device, including a touch display panel, the touch display panel including a supporting plate, a touch screen and a display panel, wherein the supporting plate is arranged between the touch screen and the display panel, and is arranged in a region corresponding to a non-active area of the touch display panel, and the supporting plate includes a supporting part used for supporting the touch screen, wherein at least part of the top surface of the supporting part is fixedly connected to the touch screen, and the top surface of the supporting part is not higher than the top surface of the touch screen to be fixed, so as to expose the entire top surface of the touch screen, and
the supporting plate further includes at least one fixing part arranged below the supporting part, and a matching part, which is capable of being fixedly connected with the fixing part, is arranged on a housing arranged around the display panel, so that the supporting plate is fixedly connected to the housing.

14. The touch display device of claim 13, wherein the fixing part is a protrusion protruding from the bottom surface of the supporting part, and the matching part is a hole corresponding to the protrusion.
